(19) United States
(12) Patent Application Publication
(10) Pub. No.: US 2008/0169862 A1
(43) Pub. Date: Jul. 17, 2008

(54) SEMICONDUCTOR DEVICE AND METHODS FOR CONTROLLING ITS PATTERNS

(75) Inventors: Joon-Soo PARK, Gyeonggi-do (KR); Gi-Sung YEO, Seoul (KR); Pan-Suk KWAK, Gyeonggi-do (KR); Han-Ku CHO, Gyeonggi-do (KR); Ji-Young LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/938,450

(22) Filed: Nov. 12, 2007

(30) Foreign Application Priority Data
Jan. 12, 2007 (KR) 2007-0003958

(51) Int. Cl. H01L 27/00; H01L 21/66

(52) U.S. Cl. 327/530; 438/8; 257/E27.001; 257/E21.53

(57) ABSTRACT

A semiconductor device and a method for controlling its patterns is described where the electrical characteristics of the patterns formed by a double patterning process may be individually controlled responsive to critical dimensions (CDs) of the patterns. The method includes controlling two or more patterns having different CDs to optimally operate the patterns. The patterns may be individually controlled by signals provided to the patterns on the basis of the pattern's CDs. The signals may be controlled by controlling the magnitudes or the application time of the signals provided to the respective patterns.

### CROSS-REFERENCE TO RELATED PATENT APPLICATION

This application claims the benefit of Korean Patent Application No. 10-2007-0003958, filed on Jan. 12, 2007, in the Korean Intellectual Property Office, the disclosure of which is incorporated herein in its entirety by reference.

### BACKGROUND OF THE INVENTION

1. Field of the Invention

The present invention relates to a semiconductor device including patterns formed by a double patterning process, and more particularly, to a semiconductor device including a control circuit for controlling device characteristics on the basis of critical dimensions of the patterns, and a method for controlling the patterns thereof.

2. Description of the Related Art

The degree of semiconductor device integration is increasing so rapidly that the resolution of exposure devices that employ a single exposure technology cannot keep up with a design rule's rate of decrease. To overcome the resolution issue of the single exposure technology, a double patterning technology has been proposed. Examples of double patterning technology include a method of forming a pattern through successive lithography processes using, for example, a double exposure technology, a method of decomposing a circuit and forming each pattern through at least two exposure/etch processes, and a method of forming one pattern and then the next pattern using a spacer sidewall.

In the double patterning process, a pattern undergoes at least two processes, for example, at least two exposure processes. For this reason, a CD (critical dimension) variation generally occurs between the first pattern and the second pattern due to various process factors. Thus, in the double patterning process, the CD distribution of each of the patterns is summed so that the total CD distribution is widened as compared to the case of the single exposure, and such widening of the CD distribution may cause the electrical characteristics of the semiconductor device to deteriorate. Furthermore, a decrease in device design rule worsens the situation by further increasing the CD distribution resulting in a considerably increased influence on the device characteristics. That is, the double patterning process is used to form a finer pattern than a critical resolution of a scanner, and in the double patterning process, the electrical characteristics of the pattern are more greatly affected by the CD as the CD of the pattern becomes smaller. Hence, the CD management of the first and second patterns and the CD distribution management are very important for good electrical characteristics of a device employing the double patterning process. However, such management incurs a high cost and requires much effort.

The CD has been conventionally managed for each semiconductor chip. However, the conventional management method is still problematic in that CD variations between patterns occur even within each semiconductor chip, making it impossible to control each device to achieve an optimum electrical characteristic, and causing a degradation problem of a device characteristic.

### SUMMARY OF THE INVENTION

Embodiments of the present invention provide a semiconductor device capable of preventing deterioration of its electrical characteristics by controlling patterns formed by a double patterning process on the basis of CDs of the patterns, and a method for controlling patterns thereof.

According to an aspect of the present invention, a method of controlling patterns of a semiconductor device comprises: controlling an operation of a first pattern responsive to a critical dimension (CD) of the first pattern; and controlling an operation of a second pattern responsive to a CD of the second pattern, wherein the CD of the first pattern is different than the CD of the second pattern. The method may also comprise providing a first signal to the first pattern; providing a second signal to the second pattern; controlling the first signal responsive to the CD of the first pattern; and controlling the second signal responsive to the CD of the second pattern.

Controlling the first and second signals may include controlling the magnitudes or the application time of the first and second signals.

The method may further comprise arranging a plurality of upper patterns over the first and second pattern so that n patterns of the upper patterns are arranged at each layer. The upper patterns may be controlled on the basis of respective CDs of the upper patterns.

The method may further comprise: providing respective signals to each of the plurality of upper patterns; and controlling the respective signals responsive to respective CDs of the plurality of upper patterns.

In another embodiment, a method of controlling patterns of a semiconductor device comprises: controlling electrical characteristics of two or more patterns formed by a double patterning process, wherein controlling the electrical characteristics is responsive to each of different critical dimensions (CDs) of the two or more patterns.

The method may also comprise: providing control signals to the two or more patterns; and individually controlling the control signals responsive to each of the different CDs.

In yet another embodiment, a semiconductor device comprises: two or more patterns arranged in a memory core and having different critical dimensions (CDs); and a control circuit for providing the two or more patterns with signals for controlling electrical characteristics of the two or more patterns responsive to the respective CDs of the two or more patterns. The control circuit may be configured to control the electrical characteristics of the two or more patterns by controlling the magnitudes or the application times of the signals responsive to the CDs of the two or more patterns. Also, two or more patterns may be arranged at different layers that are overlapped.

In another embodiment, the control circuit may be configured to individually control the signals provided to the two or more patterns for each of the layers responsive to the CDs of the patterns. Also the control circuit may include control units arranged so that two or more control units are arranged at each of the layers, wherein the control units are configured to individually control the electrical characteristics of the two or more patterns of each of the layers.

Also, the control circuit may be arranged in a peripheral circuit unit, wherein the peripheral circuit unit further comprises measuring patterns formed by the double patterning process and arranged in a same manner as the two or more patterns, and the control circuit is configured to detect the CDs of the two or more patterns using the measuring patterns, and is configured to control the electrical characteristics of the two or more patterns of the memory core responsive to the detected CDs.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view illustrating a method of forming patterns using a double patterning technology according to an embodiment of the present invention;

FIGS. 2A and 2B illustrate a semiconductor device that includes patterns formed by a double patterning process, and embodiments of a control circuit for controlling electrical characteristics of the patterns on the basis of the patterns' critical dimensions (CDs) according to an embodiment of the present invention;

FIGS. 3A and 3B illustrate a semiconductor device that includes patterns formed by a double patterning process, and embodiments of a control circuit for controlling electrical characteristics of the patterns on the basis of the patterns' CDs according to another embodiment of the present invention;

FIGS. 4A and 4B illustrate a semiconductor device that includes patterns formed by a double patterning process, and embodiments of a control circuit for controlling electrical characteristics of the patterns on the basis of the patterns' CDs according to yet another embodiment of the present invention;

FIGS. 5A and 5B illustrate a semiconductor device that includes patterns formed by a double patterning process, and embodiments of a control circuit for controlling electrical characteristics of the patterns on the basis of the patterns' CDs according to still another embodiment of the present invention; and

FIG. 6 illustrates a semiconductor device that includes patterns formed by a double patterning process, and a control circuit for controlling electrical characteristics of the patterns on the basis of the patterns' CDs according to still another embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will be omitted.

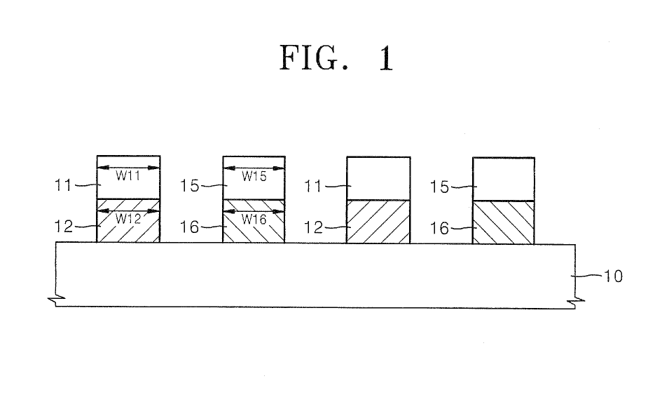

FIG. 1 is a cross-sectional view illustrating a method of forming patterns using a double patterning process according to an embodiment of the present invention. Referring to FIG. 1, a lower layer is formed on a semiconductor substrate 10, and mask patterns 11 and 15 are formed on the lower layer. The mask patterns 11 and 15 are formed by a double patterning process, and will be referred to as first mask patterns 11 and second mask patterns 15, respectively. The first mask patterns 11 are patterned first, and the second mask patterns 15 are patterned second. For example, the first mask patterns 11 may be formed on the lower layer using a general photolithography process, and the second mask patterns 15, which may be self-aligned by the first mask patterns 11, may be formed between the first mask patterns 11.

Thereafter, the lower layer may be patterned using the first and second mask patterns 11 and 15 to form first patterns 12 and second patterns 16 as shown in FIG. 1. Each of the first mask patterns 11 has a first critical dimension (CD) characterized as width W11, and each of the second mask patterns 15 has a second CD characterized as width W15. The first patterns 12 are patterned using the first mask patterns 11 as an etch mask, and have a third CD characterized as width W12, and the second patterns 16 are patterned using the second mask patterns 15 as an etch mask, and have a fourth CD characterized as width W16.

Ideally, the first CD W11 of the first mask patterns 11 is the same as the second CD W15 of the second mask patterns 15, and the third CD W12 of the first patterns 12 is the same as the fourth CD W16 of the second patterns 16. However, since the first mask patterns 11 and the second mask patterns 15 are formed through a double patterning process, the first CD W11 of the first mask patterns 11 is generally different from the second CD W15 of the second mask patterns 15. Thus, the third CD W12 of the first patterns 12 formed by the first mask patterns 11 is also generally different from the fourth CD W16 of the second patterns 16 formed by the second mask patterns 15.

Although the double patterning process, in which the first and second patterns 12 are formed in a self-aligned manner using sidewalls, is used as an example in the description, the first and second patterns 12 and 16 may be formed by a double patterning process using two photolithography processes. First to nth patterns having different CDs may be formed by repeatedly performing double patterning processes, where n is an integer that is 2 or greater.

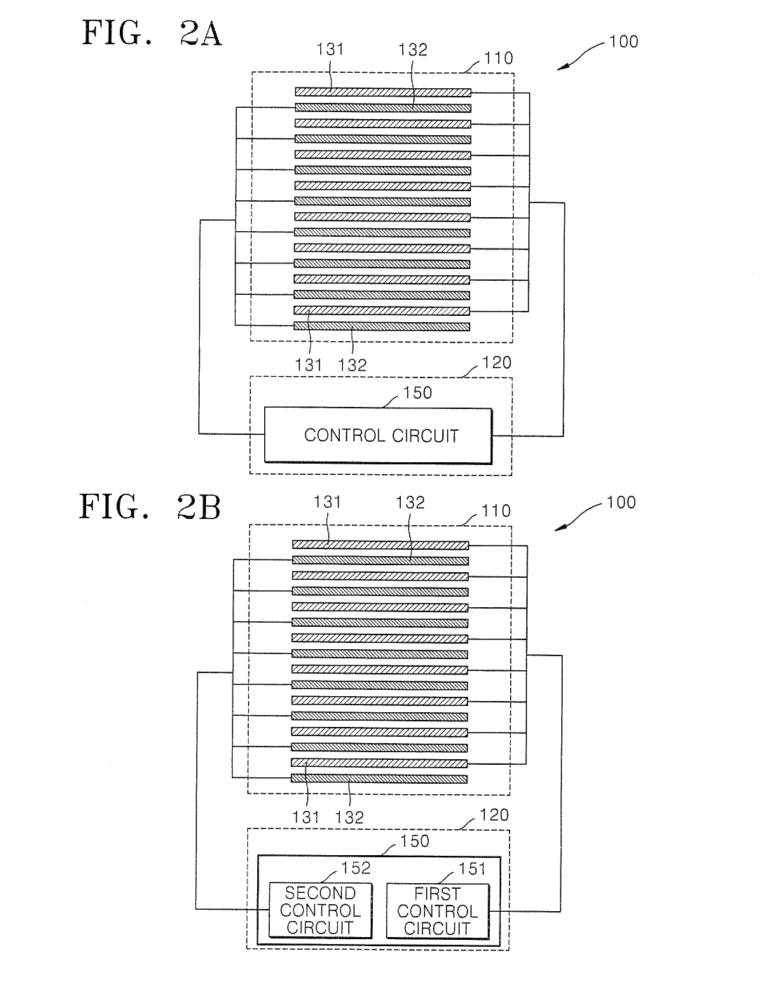

As an example, FIGS. 2A and 2B illustrate a semiconductor device 100 including patterns having different line widths, and a control circuit for controlling electrical characteristics of the patterns according to an embodiment of the present invention. The semiconductor device 100 includes a memory core 110 and a peripheral circuit unit 120. The memory core 110 includes cell arrays in which a plurality of memory cells (not shown) are arranged. The memory core 110 includes first patterns 131 and second patterns 132 (differentiated by cross-hatching) formed by a double patterning process. Each of the first patterns 131 has a first CD, and each of the second patterns 132 has a second CD, in this example. The first CD may be different from the second CD. The first patterns 131 and the second patterns 132 may be alternately arranged.

The first patterns 131 refer to patterns formed by first mask patterns, which are patterned first, and correspond to the first patterns 12 of FIG. 1. The second patterns 132 refer to patterns formed by second mask patterns, which are patterned second, and correspond to the second patterns 16 of FIG. 1.

The peripheral circuit unit 120 includes a control circuit 150 for optimally operating the first and second patterns 131 and 132, which have different CDs, with optimum electrical characteristics. The peripheral circuit unit 120 may further include a control block (not shown) for controlling cells arranged in the cell array. The control circuit 150 may be included in the control block or may be configured separately from the control block. Also, the control circuit 150 may be configured in the memory core 110, together with the first and second patterns 131 and 132.

The control circuit 150 may operate the first patterns 131 and the second patterns 132 responsive to their CDs. For example, if the first and second patterns 131 and 132 are gate patterns (or word line patterns) of a memory cell formed by double patterning processes, then the control circuit 150 may control voltages for driving the gate patterns responsive to the respective CDs of the first and second patterns 131 and 132.

For example, if the first patterns 131 have a first CD smaller than a desired CD, then the control circuit 150 may control a driving voltage applied to the first patterns 131 in due consideration of a difference between the desired CD and the first CD to optimally operate the first patterns 131. If the second patterns 132 have a second CD greater than a desired CD, then the control circuit 150 controls a driving voltage applied to the second patterns 132 in due consideration of a CD difference between the desired CD and the second CD to optimally operate the second patterns 132. In this fashion, the first and second patterns 131 and 132 have optimum electrical characteristics despite their varying CDs. Here, the control circuit 150 may control the driving voltage applied to the first and second patterns 131 and 132 by controlling the magnitude or application time of the driving voltage.

The first and second patterns 131 and 132 may include bit line patterns, or active patterns, besides the gate patterns. Thus, the patterns 131 and 132 may be controlled responsive to their respective CDs so that a precharge/discharge operation, a read/program operation, or a refresh operation of a memory cell array may be optimally performed. In such a manner, characteristic deterioration of the semiconductor device can be prevented.

The first control circuit 150 may be commonly provided for the first and second patterns 131 and 132, and may individually control the first and second patterns 131 and 132 on the basis of their CDs to optimally operate them. Also, referring to FIG. 2B, the control circuit 150 may include a first control circuit 151 and a second circuit 152 to separately control the first and second patterns 131 and 132. Here, the first control circuit 151 may be dedicated to control the first patterns 131 responsive to its CD to optimally operate the first patterns 131, and the second control circuit 152 may be dedicated to control the second patterns 132 responsive to its CD to optimally operate the second patterns 132.

In an embodiment, the control circuit 150 may directly measure the CDs of the first and second patterns 131 and 132 as well as control them on the basis of the measured CDs. In another embodiment, the control block of the peripheral circuit unit 120 may measure the CDs of the first and second patterns 131 and 132, and the control circuit 150 may control their operations on the basis of the CDs provided through the control block.

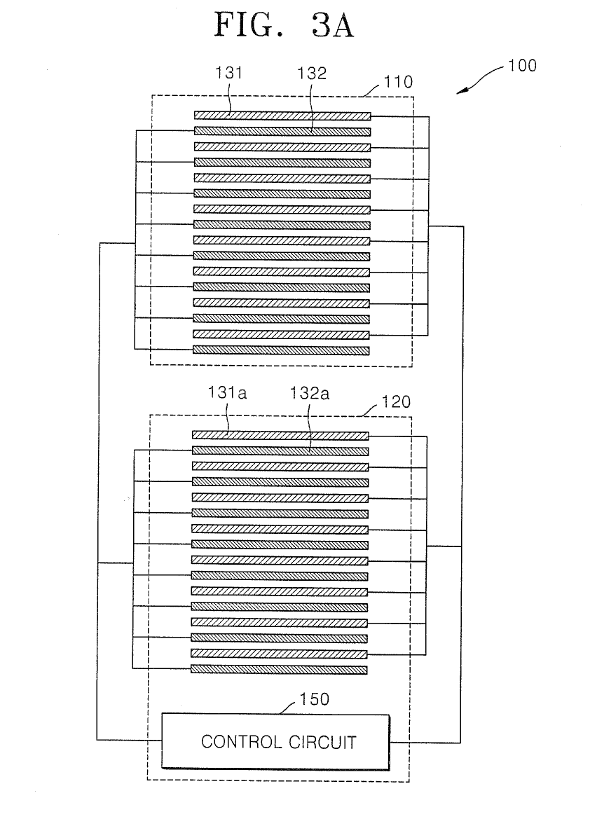

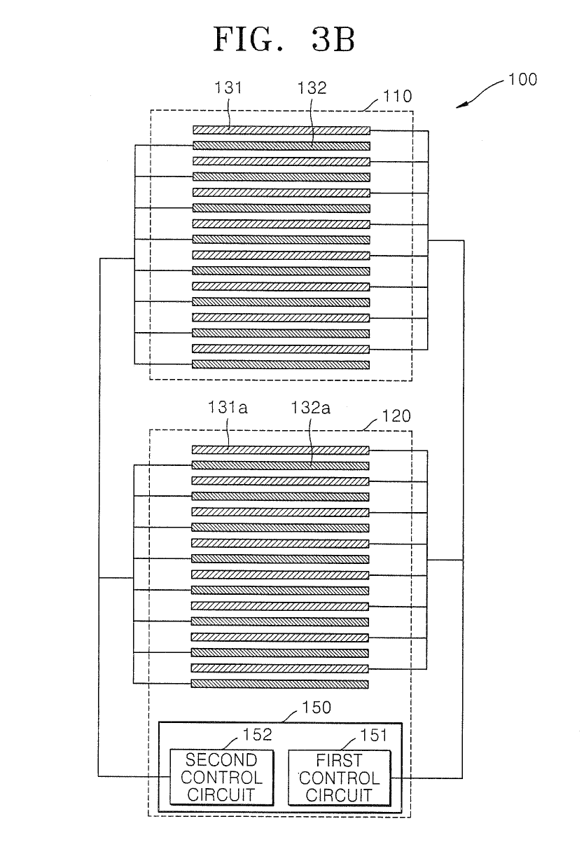

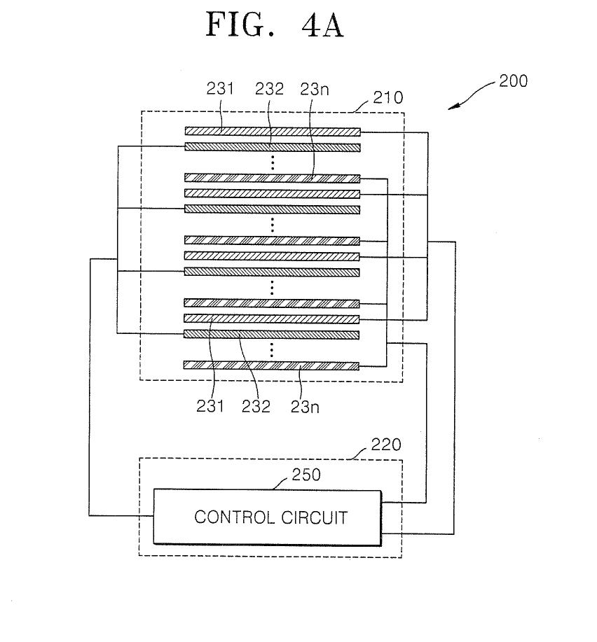

FIGS. 3A and 3B illustrate a semiconductor device 100 including patterns having different line widths, and a control circuit for controlling electrical characteristics of the patterns according to another embodiment of the present invention.

Referring to FIGS. 3A and 3B, a semiconductor device 100 includes a memory core 110 in which memory cell arrays (not shown) are arranged, and a peripheral circuit unit 120. The memory core 110 includes first patterns 131 having a first CD, and second patterns 132 having a second CD. The peripheral circuit unit 120 includes a control circuit 150 for controlling the first and second patterns 131 and 132 of the memory core 110 to optimally operate the first and second patterns 131 and 132. The peripheral circuit unit 120 further includes first measuring patterns 131a and second measuring patterns 132a for measuring CDs of the first and second patterns 131 an 132 of the memory core 110. The first and second measuring patterns 131a and 132a are arranged in the same maimer as the first and second patterns 131 and 132. When the first and second patterns 131 and 132 are formed in the memory core 110 by a double patterning process, the first and second measuring patterns 131a and 132a may be formed in the peripheral circuit unit 120 at the same time. The first measuring patterns 131a are formed using first mask patterns (11 of FIG. 1), which are patterned first, as an etch mask, and the second measuring patterns 132a are formed using second mask patterns (15 of FIG. 1), which are patterned second, as an etch mask.

The control circuit 150 may be configured to measure CDs of the first and second patterns 131 and 132 of the memory core 110 using the first and second measuring patterns 131a and 132a of the peripheral circuit unit 120, and to control the operation of the first and second patterns 131 and 132 on the basis of their respective CDs. The control circuit 150 may be commonly provided for the first and second patterns 131 and 132, and the first and second measuring patterns 131a and 132a, so that the control circuit 150 can control the first and second patterns 131 and 132 on the basis of the CDs of the first and second measuring patterns 131a and 132 to optimally operate the first and second patterns 131 and 132. Also, the control circuit 150 may include a first control circuit 151 and a second control circuit 152 to separately control the first patterns 131 and the first measuring patterns 131a, and the second patterns 132 and the second measuring patterns 132a. Here, the first control circuit 151 controls the first patterns 131 on the basis of the CD of the first measuring patterns 131a to optimally operate the first patterns 131, and the second control circuit 152 controls the second patterns 132 on the basis of the CD of the second measuring patterns 132 to optimally operate the second patterns 132.

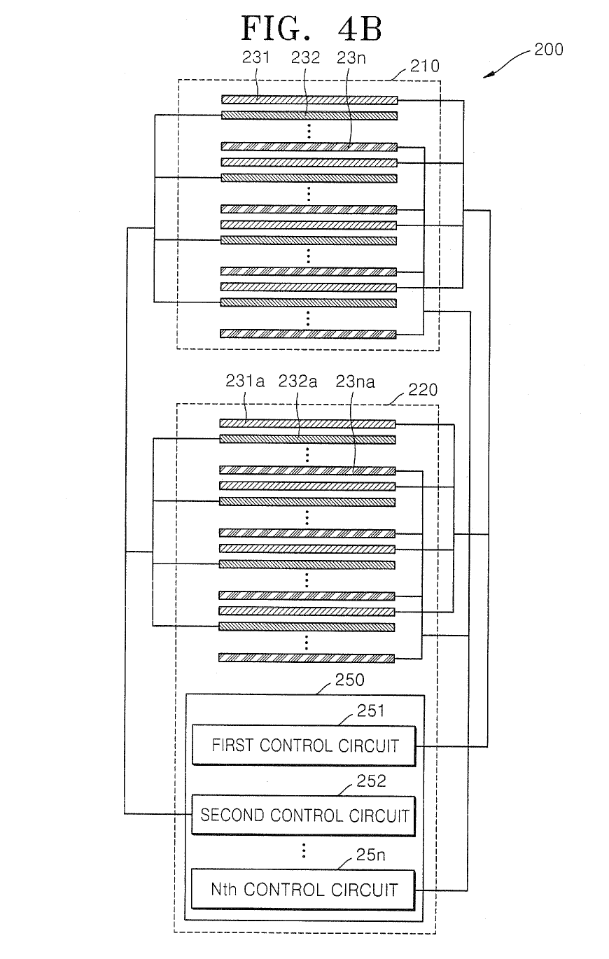

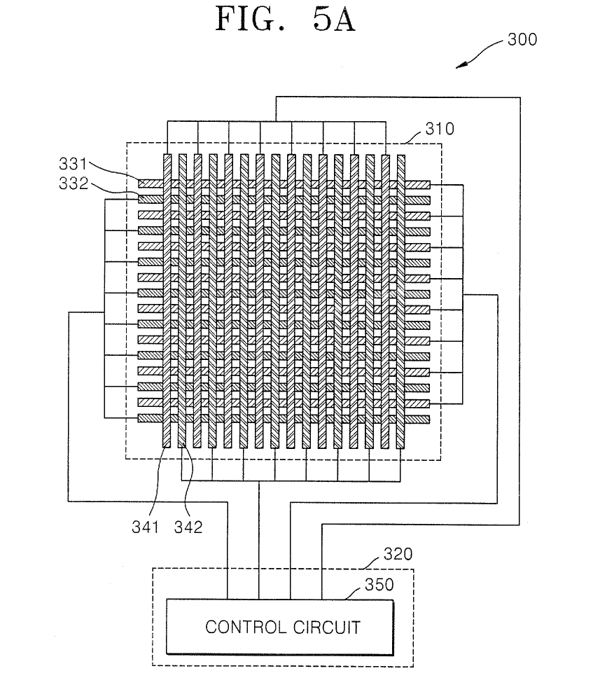

FIGS. 4A and 4B illustrate a semiconductor device 200 including patterns having different line widths, and a control circuit for controlling the patterns to facilitate optimum operation of the patterns according to another embodiment of the present invention.

Referring to FIGS. 4A and 4B, the semiconductor device 200 includes a memory core 210 and a peripheral circuit unit 220. The memory core 210 includes first patterns 231 having a first CD, second patterns 232 having a second CD, . . . , and nth patterns 23n having an nth CD. The first to nth CDs of the first to nth patterns 231 to 23n may each be different values.

The first to nth patterns 231 to 23n are formed by a double patterning process and sets of first to nth patterns 231 to 23n may be repetitively arranged. The first patterns 231 refer to patterns formed by first mask patterns, which are patterned first, the second patterns 232 refer to patterns formed by second mask patterns, which are patterned second, and the nth patterns 23n refer to patterns formed by nth mask patterns, which are patterned in the nth order.

The peripheral circuit unit 220 includes a control circuit 250 for controlling the first to nth patterns 231 to 23n having different CDs to optimally operate the first to nth patterns 231 to 23n. Thus optimum electrical characteristics of the first to nth patterns 231 to 23n may be achieved. The peripheral circuit unit 220 may further include a control block (not shown) for controlling cells arranged in cell arrays (not shown), and the control circuit 250 may be included within the control block or may be configured separately from the control block. Also, the control circuit 250 may be configured in the memory core 210, together with the first to nth patterns 231 to 23n.

As illustrated in FIG. 4B, the peripheral circuit unit 220 may further include first measuring patterns 231a to nth measuring patterns 23na for measuring the CDs of the first to nth patterns 231 to 23n of the memory core 210. When the first to nth patterns 231 to 23n are formed in the memory core 210 by a double patterning process, the first to nth measuring patterns 231a to 23na may be formed in the peripheral circuit unit 220 at the same time. The first measuring patterns 231a are formed using as an etch mask first mask patterns, which are patterned first, the second measuring patterns 232a are formed using as an etch mask second mask patterns, which are patterned second, and the nth measuring patterns 23na are formed using as an etch mask nth mask patterns, which are patterned in the nth step.

The control circuit 250 may individually operate the first to nth patterns 231 to 23n on the basis of the respective CDs of the first to nth patterns 231 to 23n. The control circuit 250 may be commonly provided for the first to nth patterns 231 to 23n, so that the control circuit 250 can individually control the first to nth patterns 231 to 23n with reference to their respective CDs to optimally operate the first to nth patterns 231 to 23n. Also, the control circuit 250 may include a first control circuit 251, a second control circuit 252, up to an nth control circuit 25n to separately control the first to nth patterns 231 to 23n. Here, the first control circuit 251 may control the first patterns 231 on the basis of their CD to optimally operate the first patterns 231, the second control circuit 252 may control the second patterns 232 on the basis of their CD to optimally operate the second patterns 232, and the nth control circuit 25n may control the nth patterns 23n on the basis of their CD to optimally operate the nth patterns 23n.

The control circuit 250 may directly measure the CDs of the first to nth patterns 231 to 23n, and control them on the basis of the measured CDs. In another embodiment, the control block of the peripheral circuit unit 220 may measure the CDs of the first to nth patterns 231 to 23n, and the control circuit 250 may control them on the basis of the CDs measured through the control block. The control circuit 250 can measure the respective CDs of the first to nth patterns 231 to 23n on the basis of a value of a current flowing through the respective patterns 231 to 23n, for example.

Also, the control circuit 250 may measure the CDs of the first to nth patterns 231 to 23n of the memory core 210 using the first to nth measuring patterns 231a to 23na of the peripheral circuit unit 220, and may control the first to nth patterns 231a to 23na on the basis of the measured CDs, respectively.

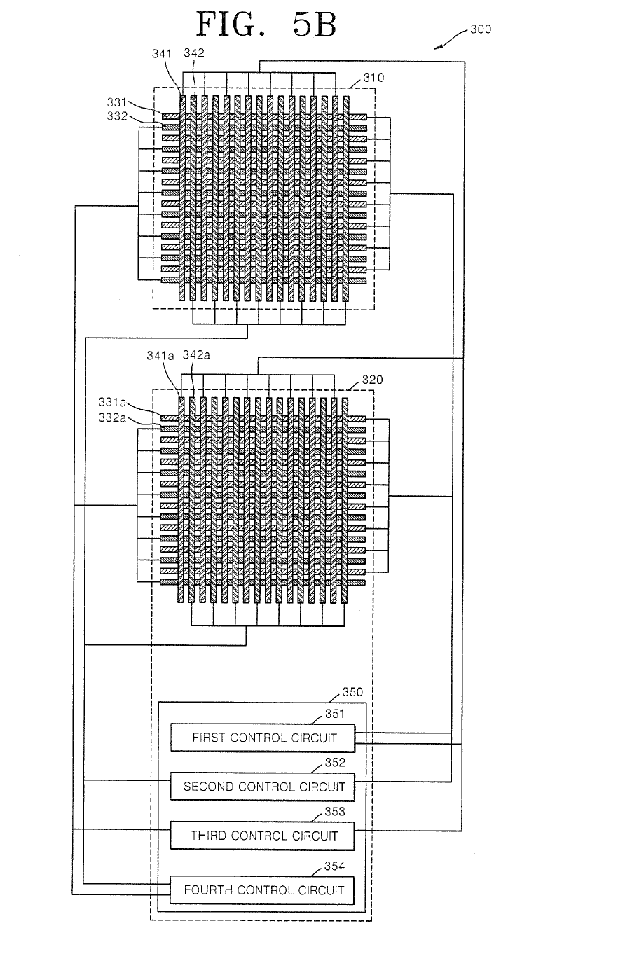

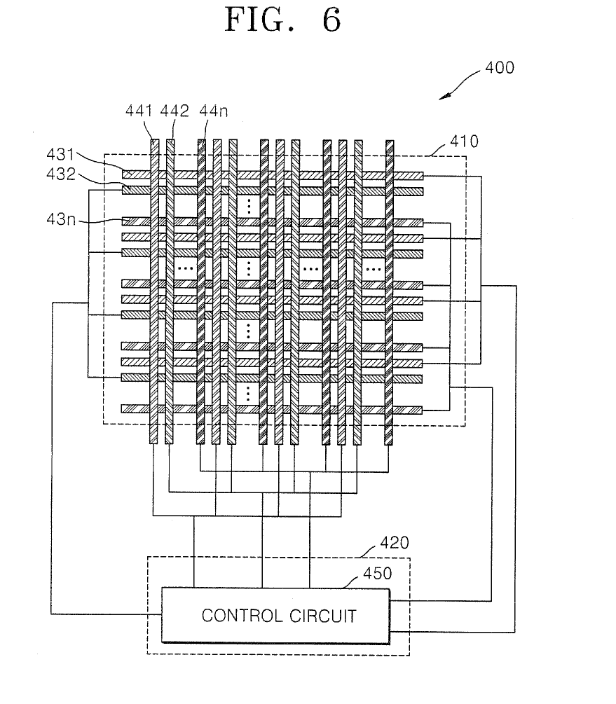

FIGS. 5A and 5B illustrate a semiconductor device 300 including patterns having different line widths, and a control circuit for controlling the patterns to operate optimally, according to another embodiment of the present invention.

Referring to FIGS. 5A and 5B, the semiconductor device 300 includes a memory core 310 and a peripheral circuit unit 320. The memory core 310 includes first and second lower patterns 331 and 332, and first and second upper patterns 341 and 342 that are arranged at different layers. In this example embodiment, the first and second lower patterns 331 and 332 and the first and second upper patterns 341 and 342 have different CDs from each other. The first and second lower patterns 331 and 332 and the first and second upper patterns 341 and 342 are alternately arranged. The first and second lower patterns 331 and 332 may overlap and intersect the first and second upper patterns 341 and 342. The first lower patterns 331 refer to patterns formed by first mask patterns, which are patterned first during a double patterning process of a lower layer (not shown), and the second lower patterns 332 refer to patterns formed by second mask patterns, which are patterned second during the double patterning process of the lower layer. The first upper patterns 341 refer to patterns formed by first mask patterns, which are patterned first during a double patterning process of an upper layer (not shown), and the second upper patterns 342 refer to patterns formed by second mask patterns, which are patterned second during the double patterning process of the upper layer.

The peripheral circuit unit 320 includes a control circuit 350 for optimally operating the first and second lower patterns 331 and 332, and the first and second upper patterns 341 and 342 having different CDs. The peripheral circuit unit 320 may further include a control block (not shown) for controlling cells arranged in cell arrays (not shown), and the control circuit 350 may be included within the control block or may be constructed separately from the control block. Also, the control circuit 350 may be configured in the memory core 310, together with the first and second lower patterns 331 and 332, and the first and second upper patterns 341 and 342.

The peripheral circuit unit 320 further includes first lower measuring patterns 331a and second lower measuring patterns 332a for measuring CDs of the first and second lower patterns 331 and 332 of the memory core 310, and first upper measuring patterns 341a and second upper measuring patterns 342a for measuring CDs of the first and second upper patterns 341 and 342 of the memory core 310. The first and second lower measuring patterns 331a and 332a are arranged in the same maimer as the first and second lower patterns 331 and 332, and the first and second upper measuring patterns 341a and 342a are arranged in the same manner as the first and second upper patterns 341 and 342. When the first and second lower patterns 331 and 332 are formed in the memory core 310 by a double patterning process, the first and second lower measuring patterns 331a and 332a are formed in the peripheral circuit unit 320 at the same time. Similarly, when the first and second upper patterns 341 and 342 are formed by a double patterning process, the first and second upper measuring patterns 341a and 342a are formed at the same time. The first upper and lower measuring patterns 341a and 331a are formed using as an etch mask first mask patterns (11 of FIG. 1), which are patterned first, and the second upper and lower measuring patterns 342a and 332a are formed using as an etch mask second mask patterns (15 of FIG. 1), which are patterned second.

The control circuit 350 individually operates the first and second lower patterns 331 and 332 and the first and second upper patterns 341 and 342 for each layer on the basis of their CDs. For example, if the first and second lower patterns 331 and 332 and the first and second upper patterns 341 and 342 are gate patterns (or word line patterns) and bit line patterns, respectively, of a memory cell formed by a double patterning process, then the control circuit 350 may control a voltage for driving the gate patterns on the basis of the CDs of the first and second lower patterns 331 and 332, and controls a voltage for driving the bit line patterns on the basis of the CDs of the first and second upper patterns 341 and 342.

The control circuit 350 may be commonly provided for the first and second lower patterns 331 and 332 and the first and second upper patterns 341, so that the control circuit 350 can individually control the first and second lower patterns 331 and 332 and the first and second upper patterns 341 and 342 for each layer on the basis of their CDs. Also, the control circuit 350 may include first and second control circuits 351 and 352, and third and fourth control circuits 353 and 354 to separately control the first and second lower patterns 331 and 332, and the first and second upper patterns 341 and 342, respectively. Here, the first and second control circuits 351 and 352 may control the first and second lower patterns 331 and 332, respectively, to optimally operate the first and second lower patterns 331 and 332, and the third and fourth control circuits 353 and 354 may control the first and second upper patterns 341 and 342, respectively, to optimally operate the first and second upper patterns 341 and 342.

The control circuit 350 may simultaneously control patterns of different layers on the basis of CDs of the patterns of the different layers. The control circuit 350 may simultaneously control the first lower pattern 331 and the first upper pattern 341 on the basis of their CDs, and simultaneously control the first lower patterns 331 and the second upper patterns 342 on the basis of their CDs. Also, the control circuit 350 may simultaneously control the second lower patterns 332 and the first upper patterns 341 on the basis of their CDs, and simultaneously control the second lower patterns 332 and the second upper patterns 342 on the basis of their CDs.

For example, if the first and second lower patterns 331 and 332 are active patterns, and the first and second upper patterns 341 and 342 are gate patterns, the control circuit 350 may simultaneously control the first lower patterns 331 and the first upper patterns 341 on the basis of their respective CD, and simultaneously control the second lower patterns 332 and the second upper patterns 342 on the basis of their respective CD.

Furthermore, the control circuit 350 may include the first to fourth control circuits 351 to 354 so that the first control circuit 351 may simultaneously control the first lower patterns 331 and the first upper patterns 341, the second control circuit 352 may control the first lower patterns 331 and the second upper patterns 342, the third control circuit 353 may control the second lower patterns 332 and the first upper patterns 341, and the fourth control circuit 354 may control the second lower patterns 332 and the second upper patterns 342 on the basis of the CDs of the corresponding patterns. One control circuit 350 may be arranged at each layer to individually control patterns at each layer.

The control circuit 350 may control the first and second lower patterns 331 and 332 and the first and second upper patterns 341 and 342, as well as directly measure their CDs, the control being responsive to the measured CDs. In another embodiment, the control block of the peripheral circuit unit 320 may measure the CDs of the first and second lower patterns 331 and 332 and the first and second upper patterns 341 and 342, and the control circuit 350 may control the first and second lower patterns 331 and 332 and the first and second upper patterns 341 and 342 on the basis of the CDs provided through the control block.

The control circuit 350 may measure the CDs of the first and second lower patterns 331 and 332 of the memory core 310 using the first and second lower measuring patterns 331a and 332a of the peripheral circuit unit 320, and thus control the first and second lower patterns 331 and 332 on the basis of the measured CDs of the corresponding patterns. Also, the control circuit 350 may measure the CDs of the first and second upper patterns 341 and 342 using the first and second upper measuring patterns 341a and 342a, and control the first and second upper patterns 341 and 342 on the basis of the measured CDs of the corresponding patterns.

FIG. 6 illustrates a semiconductor device 400 including patterns having different line widths, and a control circuit for controlling the patterns to optimally operate the patterns according to another embodiment of the present invention. Referring to FIG.6, the semiconductor device 400 includes a memory core 410 and a peripheral circuit unit 420. The memory core 410 includes first to nth lower patterns 431 to 43n having different CDs, and first to nth upper patterns 441 to 44n having different CDs. The upper patterns 441 to 44n and the lower patterns 431 to 43n may be repetitively stacked in the memory core 410.

The peripheral circuit unit 420 includes a control circuit 450 for optimally operating the first to nth upper and lower patterns 441 to 44n and 431 to 43n. The peripheral circuit unit 420 may further include first to nth upper and lower measuring patterns as in the above-described embodiment. The control circuit 450 may be included within a control block or may be configured separately from the control block. Also, the control circuit 450 may be configured within the memory core 410.

The control circuit 450 may measure CDs of the first to nth upper and lower patterns 441 to 44n and 431 to 43n stacked at multiple layers, and individually control patterns in each layer, or simultaneously control the patterns of different layers.

According to embodiments of the present invention, a circuit is provided to measure the CDs of double-patterned patterns arranged in a memory core, so that each of the patterns is controlled on the basis of the measured CD of each pattern, and thus each pattern can be operated to have optimum electrical characteristics. Accordingly, characteristic deterioration of the device due to CD variations between patterns can be eliminated. Also, management of the CDs of respective patterns is not required, and thus cost and time for CD management can be saved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of controlling patterns of a semiconductor device, the method comprising:
forming a first pattern in a first exposure and forming a second pattern in a second exposure;
measuring a critical dimension (CD) of each of the first pattern and the second pattern;
controlling an operation of the first pattern responsive to the (CD) of the first pattern; and
controlling an operation of the second pattern responsive to the CD of the second pattern, wherein the CD of the first pattern is different than the CD of the second pattern.

2. The method of claim 1, further comprising:
providing a first signal to the first pattern;
providing a second signal to the second pattern;
controlling the first signal responsive to the CD of the first pattern; and
controlling the second signal responsive to the CD of the second pattern.

3. The method of claim 2, wherein controlling the first and second signals includes controlling the magnitudes or the application time of the first and second signals.

4. The method of claim 1, further comprising arranging a plurality of upper patterns over the first and second patterns so that n patterns of the upper patterns are arranged at each layer.

5. The method of claim 4, wherein the upper patterns are controlled on the basis of respective CDs of the upper patterns.

6. The method of claim 5, further comprising:
providing respective signals to each of the plurality of upper patterns; and
controlling the respective signals responsive to respective to the provided respective signals.

7. The method of claim 6, wherein the upper patterns are controlled by controlling the magnitudes or the application times of the respective signals.

8. The method of claim 4, further comprising:
providing signals to the first pattern, the second pattern, and the upper patterns; and
individually controlling the signals responsive to the respective CDs of the first pattern, the second pattern, and the upper patterns.

9. The method of claim 4, further comprising:
providing signals to the first pattern, the second pattern, and the upper patterns; and
simultaneously controlling the signals responsive to the respective CDs of the first pattern, the second pattern, and the upper patterns.

10. A method of controlling patterns of a semiconductor device, the method comprising controlling electrical characteristics of two or more patterns formed by a double patterning process, wherein controlling the electrical characteristics is responsive to each of different critical dimensions (CDs) of the two or more patterns.

11. The method of claim 10, further comprising:
providing control signals to the two or more patterns; and
individually controlling the control signals responsive to each of the different CDs.

12. The method of claim 11, wherein individually controlling the control signals comprises controlling the magnitudes or the application times of the control signals.

13. The method of claim 11, wherein the two or more patterns are arranged at different layers.

14. The method of claim 13, further comprising individually controlling the control signals provided to the patterns for each of the layers responsive to the CDs of the two or more patterns.

15. The method of claim 14, further comprising controlling the magnitudes or the application time of the control signals provided to the two or more patterns for each of the layers.

16. The method of claim 13, further comprising simultaneously controlling the control signals applied to the two or more patterns arranged at the different layers responsive to the CDs of the patterns.

17. A semiconductor device comprising:
two or more patterns arranged in a memory core and having different critical dimensions (CDs); and
a control circuit for providing the two or more patterns with signals for controlling electrical characteristics of the two or more patterns responsive to the respective CDs of the two or more patterns.

18. The semiconductor device of claim 17, wherein the control circuit is configured to control the electrical characteristics of the two or more patterns by controlling the magnitudes or the application times of the signals responsive to the CDs of the two or more patterns.

19. The semiconductor device of claim 17, wherein the two or more patterns are arranged at different layers that are overlapped.

20. The semiconductor device of claim 19, wherein the control circuit is configured to individually control the signals provided to the two or more patterns for each of the layers responsive to the CDs of the patterns.

21. The semiconductor device of claim 20, wherein the control circuit includes control units arranged so that two or more control units are arranged at each of the layers, wherein the control units are configured to individually control the electrical characteristics of the two or more patterns of each of the layers.

22. The semiconductor device of claim 20, wherein the control circuit includes two or more control units, each simultaneously controlling an electrical characteristic of a corresponding pattern of the two or more patterns of the layers.

23. The semiconductor device of claim 19, wherein the control circuit is configured to simultaneously control the signals applied to the two or more patterns arranged at the different layers responsive to the CDs of the two or more patterns.

24. The semiconductor device of claim 17, wherein the control circuit is arranged in the memory core or a peripheral circuit unit.

25. The semiconductor device of claim 17, wherein the patterns are formed by a double patterning process.

26. The semiconductor device of claim 25, wherein the control circuit is arranged in a peripheral circuit unit,
wherein the peripheral circuit unit further comprises measuring patterns formed by the double patterning process and arranged in a same manner as the two or more patterns, and
the control circuit being configured to detect the CDs of the two or more patterns using the measuring patterns, and being further configured to control the electrical characteristics of the two or more patterns of the memory core responsive to the detected CDs.

27. The semiconductor device of claim 17, wherein the signals comprise a driving voltage and the driving voltage provided from the control circuit to the two or more patterns is different for at least two of the patterns.

28. The semiconductor device of claim 17, wherein the patterns are selected from the group consisting of bit line patterns, active patterns, or gate patterns.
